(19) United States
(12) Patent Application Publication
(10) Pub. No.: US 2014/0077800 A1
(43) Pub. Date: Mar. 20, 2014

(54) MAGNETIC FIELD APPARATUS AND METHOD OF OPERATING A MAGNETIC FIELD APPARATUS

(71) Applicants: SIEMENS AG, Muenchen (DE); MAX-DELBRUECK-CENTRUM FUER MOLEKULARE MEDIZIN, Berlin (DE)

(72) Inventors: Tobias Frauenrath, Hueckelhoven (DE); Thoralf Niendorf, Aachen (DE); Wolfgang Renz, Erlangen (DE)

(73) Assignees: SIEMENS AG, Muenchen (DE); MAX-DELBRUECK-CENTRUM FUER MOLEKULARE MEDIZIN, Berlin (DE)

(21) Appl. No.: 14/001,506

(22) PCT Filed: Feb. 25, 2011
(86) PCT No.: PCT/EP2011/052801

§ 371 Date: Dec. 4, 2013

(51) Int. Cl. G01R 33/563

(52) U.S. Cl. CPC G01R 33/5635
USPC 324/306; 324/322; 324/309

(57) ABSTRACT

A magnetic field apparatus comprises a generator for generating a magnetic field of the magnetic field apparatus and a sensor for measuring the interaction between electrical charge carriers in an object and the magnetic field, wherein the electrical as charge carriers and the magnetic field are in relative motion to each other. The magnetic field apparatus may in particular be an MRI apparatus and the sensor may use the magnetohydrodynamic effect for deriving a cardiac trigger signal at any target area positioned off-centre to the heart.

The present invention relates in general to a magnetic field apparatus, a method of operating a magnetic field apparatus and the use of an magnetic field apparatus.

A magnetic field is a force that is created by a magnet or by moving electric charges. A magnetic field can for example be used for Magnetic Resonance Imaging (MRI), which is a imaging technique used to visualize detailed internal structures. The MRI depends on the generation of strong and uniform magnetic fields. A major specification of the static field in MRI is that it has to be substantially homogeneous over a predetermined region, known in the art as the “diameter spherical imaging volume” or “dsv.” Errors or variation of less than 20 parts per million peak-to-peak (or 10 parts per million rms) are typically required for the dsv.

MRI equipment has undergone a number of refinements since the introduction of the first closed cylindrical systems. In particular, improvements have occurred in quality/resolution of images through improved signal to noise ratios and introduction of high and ultra high field magnets. Improved resolution of images, in turn, has led to MRI being a modality of choice for an increasing number of specialists for both structural anatomical and functional human MRI imaging.

The basic components of a typical magnetic resonance system for producing images for human studies include a main magnet (usually a superconducting magnet which produces the substantially homogeneous magnetic field (the Bₒ·field) in the dsv), one or more sets of shim coils, a set of gradient coils, and one or more RF coils.

As MRI is not done in real time, it is necessary to synchronise imaging with motion. In the state of the art, it is desirable to obtain diagnostic quality ECG signals while a patient is being monitored in a MRI system. Electrocardiogram (ECG) signals are based on the surface potentials of the heart. Current ECG with filtering on MRI systems only allows gating. However, triggering is also available. Such ECG gating provides information regarding what part of the heart cycle the heart is at for purposes of triggering an MRI image to be taken at the desired point in the heart cycle. In addition, ECG triggering can also be difficult on standard 3T or higher MRI systems due to distortions of the ECG signal.

Accordingly, there is currently no diagnostic quality ECG system that can be used in the MRI system. The primary reason that it is not easy to obtain adequate ECG quality on standard 3T or higher MRI systems is the magneto-hydrodynamics (MHD) flow voltages, which are due to the flow of blood in the static magnetic field of the MRI system. The MHD flow voltages can have the same spectral characteristics as the true heart electrophysiological polarization signals and are thus difficult to extract. These MHD flow voltages are due to the flow of blood, which is a conductor, in a direction perpendicular with the static magnetic field, or other magnetic fields, of the MRI system. In fact, blood vessels can experience a force on them due to blood flow in the static magnetic field of the MRI system. It can be difficult, if even possible, to separate the true ECG signal from the signals produced by the heart pushing the blood through the vessels around the heart, which is problematic for triggering and for the imaging in general.

To differentiate the ECG signal from the signal generated by the MHD effect, methods have been described in the state of the art. For example, it has been proposed to use a 12-lead MRI compatible ECG instead of a standard 4-lead ECG, in order clearly separate MHD signal from ECG signals. Furthermore, it has been described to apply an adaptive filtering procedure to separate between the real ECG and the MHD signals. However, the compensation and elimination of the MHD effect is not sufficient to reduce the distortions, artifacts and noise caused by the MHD effect.

The MHD effect can be used to measure small angular displacements. For example, U.S. Pat. No. 6,173,611 B1 describes a self-contained MHD sensor for measuring the angular rate of displacement about a central axis from one hertz to 2,000 Hz. The sensor includes an exterior case made from a material having high magnetic permeability and an insulated cylindrical conductive fluid channel extending along the inside of the case. The insulated cylindrical channel includes therein a conductive fluid such as mercury which acts as an inertial proof mass. The cylinder of mercury and exterior case can rotate with respect to each other when small angular displacements are imparted to the case. Furthermore, the sensor includes a permanent magnet structure within the exterior cylindrical case to generate a radial magnetic field which has a component extending perpendicular to a wall of the fluid channel.

It was an object of the invention to provide an apparatus and/or method which overcome the disadvantages of the aforementioned state of the art.

In a first aspect the invention is directed towards a magnetic field apparatus with a generator for generating a magnetic field of the magnetic field apparatus and a sensor for measuring the interaction between electrical charge carriers in an object and the magnetic field, wherein the electrical charge carriers and the magnetic field are in relative motion to each other.

The term magnetic field apparatus broadly encompasses devices capable of generating a magnetic field. Further, magnetic resonance systems like magnetic resonance image (MRI) devices, nuclear magnetic resonance (NMR) devices and electron spin resonance (ESR) devices are encompassed. The inventive magnetic field apparatus applies both to spectroscopy and to imaging and can for example be utilized in the fields of medicine, physics, material and geological sciences and archaeology, such as age determination or non-destructive analysis of inner structures. The term object accordingly covers besides any physical object also the body of a human or an animal. Further examples can be the examination of the function of a prosthetic heart valve or examinations in the material sciences where the flow behaviour of charge carriers is of interest.

The electrical charge carriers may be part of the object or they can be introduced into the object for the measurement. It is also possible to introduce additional electrical charge carriers into an object or to enhance them in the object.

The invention utilizes the interaction between electrical charge carriers for example in blood and the magnetic field of the magnetic field apparatus. The electrical charge carriers and the magnetic field are in relative motion to each other. Either the electrical charge carriers are flowing in a liquid or a gas through a magnetic field or the magnetic field moved with respect to the position of the electrical charge carrier. More precisely the invention uses the magnetohydrodynamic (MHD) effect. According to the MHD effect the interaction of electrical charge carriers and a magnetic field being in relative motion to each other creates a potential difference which can be measured by one or more sensors or electrodes at least two measuring points. The MHD effect depends on the strength of the magnetic field, the length of the distance travelled by the charge carriers between the measuring points at which the potential is tapped, the speed of the charge carriers or of the magnetic field changes, the concentration or density of the charge carriers, the volume/unit time flow of the charge carriers and/or the flow direction of the charge carriers relative to the magnetic field.

It is an advantage of the present invention that characteristics and/or quantity of the magnetic field and/or of the object can be measured in a simple manner in a magnetic field. No special equipment especially suitable for strong magnetic fields is needed.

The sensor may be an electric field sensor for example with two electrodes to measure the potential difference induced by the magnetic field. The sensor may be an electrode or a probe.

The magnetic field apparatus may have at least two sensors. Instead of one sensor a plurality of sensors can be utilized to measure the interaction between the electrical charge carriers and the magnetic field. This can improve accuracy and extent of the measurement.

The sensor may be adapted to measure an electrical potential difference in the magnetic field of the magnetic field apparatus. This way the MHD effect can be captured best. Instead of the potential difference a current can be measured in the case of conductive materials. However, the current is reduced and/or gets distorted by the resistance of the material.

The magnetic field apparatus may be an MR apparatus and may have a control unit for synchronization of the acquisition, analysis and/or reconstruction of MR data, wherein the control unit may be in communication with the sensor. For a synchronization or triggering of an MR apparatus like an NMR or MRI apparatus the measurement of the interaction or the potential difference in the magnetic field of the MR apparatus can occur at the same time as the heart activity or at the same time as the flow behaviour of e.g. blood. The potential measurement of MHD induced signals in a region of the body allows conclusions with regard to the heart activity, the temporal phase within the cardiac cycle and/or the flow behaviour and/or the flow velocity of blood or the periodicity of any moving electrical charge carrier. These signals can be utilized for a synchronization of MR imaging/spectroscopy with the cardiac cycle and/or the blood flow behaviour. This gives for the first time a trigger information, which can be derived from flowing charge carriers directly at or close to the position of any target anatomy to be imaged. Before, trigger information could only be extracted at the heart using electrophysiological information of the cardiac cycle, which results in unknown delays between the electrophysiological activity derived from the heart and the blood pulsation/blood flow at any target area positioned off-center to the heart Now, with the trigger derived from the target area there is no extra delay between the cardiac cycle or the cycle of the blood flow behaviour and the trigger mechanism (here the MHD signal) at the target.

The magnetic field apparatus may have a secondary generator for generating a test field, wherein the sensor may detect a direction of a vessel of the object based on the test field. The secondary generator may be part of the generator or may be an additional generator internal or external to the magnetic field apparatus. Gradient coils of the magnetic field apparatus may for example generate the test field. The vessel may be a conduct or pipe of an object or part of the bodies vasculature. With the MHD effect directional information of the vessel can be achieved. The amplitude of the MHD signal depends on the orientation of the vessel with respect to the main axis of the magnetic field. A maximum of the signal indicates a vessel perpendicular to the magnetic field. This can be used for example to prepare for special MR techniques like MR angiography as these imaging techniques usually require an orientation of the slice to be imaged perpendicular to the flow direction. Further examples can be the examination of the function of a prosthetic heart valve or examinations in the material sciences.

The object may be a probe which can be freely positioned in the magnetic field and the sensor may be attached to the probe for measuring the strength, the spatial distribution, the temporal evolution and/or an angle of the magnetic field. The probe may comprise a vessel through which the electrical charge carriers flow. The probe can be positioned at different coordinates inside the magnetic field. The signals measured at the different coordinates are proportional to the magnetic field. This allows the creation of a map of the magnetic field with simple means. The sensitivity of the measurement can be improved by increasing the distance between the measuring points, by increasing the flow velocity, the concentration or the density of the electric charge carriers.

In a second aspect the invention is directed towards a method for operating a magnetic field apparatus, the method comprising:
measuring the interaction between electrical charge carriers of an object and the magnetic field of the magnetic field apparatus;
synchronisation of the acquisition, analysis and/or reconstruction of MR data of the magnetic field apparatus based on the measured interaction; and/or
determination of a direction of a vessel of the object based on the measured interaction; and/or
characterization of a magnetic field of the magnetic field apparatus based on the measured interaction.

The same advantages and modifications as described above apply here as well. The characterization of the magnetic field includes a quantitative measurement of the strength and/or the spatial distribution and/or direction or angle of the magnetic field.

The measurement may utilize a magnetohydrodynamic (MHD) effect. The MHD effect was previously seen as an unwanted effect which distorts ECG signals. Here, the MHD effect is utilized deliberately for better handling of MR data and/or MR imaging, the determination of a direction of a vessel and/or the characterization of a magnetic field.

An electrical potential difference in the magnetic field of the magnetic field apparatus may be measured. The interaction can be easily measured by determining a potential difference between two measuring points.

In a third aspect the invention is directed towards a use of a magnetic field apparatus for imaging and/or spectroscopy, wherein the apparatus employs the magnetohydrodynamic effect. It was very surprising that the magnetohydrodynamic effect can be utilized for imaging and/or spectroscopy. The apparatus can be an MR apparatus such as an MRI or a NMR apparatus. The apparatus can also be configured to be an ESR apparatus. The apparatus can be used for magnetic resonance imaging (MRI), which is an imaging technique used primarily in medical settings to produce high quality images of the inside of the human body. Magnetic resonance imaging is based on the absorption and emission of energy in the radio frequency range of the electromagnetic spectrum, in particular by producing images based on spatial variations in the phase and frequency of the radio frequency energy being absorbed and emitted by the imaged object. The apparatus can be used for various imaging techniques for example: gradient-echo based imaging, spin-echo based imaging, single or multislice imaging, volume imaging (3D imaging), multi-oblique imaging, inversion recovery imaging or other MR imaging techniques. Moreover, the magnetic field apparatus can be utilized for spectroscopy. Magnetic resonance spectroscopy (MRS) is a noninvasive technique that can be applied to measure the concentrations of chemical components within tissues. The technique is based on the same physical principles as magnetic resonance imaging (MRI). MRI and MRS have in common, that the emitted radiofrequency is based on the concentration and spatial position of nuclei, with the exception that MRI usually but necessarily detects the signal of free water while MRS detects the chemical composition of tissue, cells or any other material. The information produced by MRS is preferably displayed graphically as a spectrum with peaks consistent with the various chemicals detected. MRS can be performed as an adjunct to MRI. MR imaging can be performed resolve the chemical composition of tissue, cells or any other material.

Such as MRI, MRS can be applied to every organ of the body e.g. brain, heart, liver, kidney, prostate, and extremities. MRS can preferably be used for analyzing disorders of metabolism, tumors and certain inflammatory and ischemic diseases. It can be used for early diagnostic detection procedure but also for measuring spectroscopic changes in a variety of enzyme deficiencies, mitochondrial abnormalities, dystrophies, inflammatory myopathies, and thyroid disease. In muscle these diseases include preferably phosphofructokinase deficiency, amyloglucosidase deficiency, Duchenne muscular dystrophy, Becker muscular dystrophy, dermatomyositis, polymyositis, inclusion body myositis, hypothyroidism, and congestive heart failure.

It is preferred that the magnetic field apparatus can be used for the synchronisation of the acquisition, analysis and/or reconstruction of MR data with at least one time- and/or space-varying property of an object or parts thereof. The quality of imaging or spectroscopy can be improved by the synchronisation of the MR data with a time- and/or space-varying property of an object or parts thereof. The object is for example a human or animal body or any other object. The parts thereof are preferably organs, tissue or vessel such as a conduct or pipe or a vascular of a body. The synchronization or triggering of an magnetic field apparatus can occur in parallel to the heart activity or to the flow behaviour of e.g. blood or any other carrier of electrical charges. The measurement of MHD induced signals in a region of a body allows conclusions with regard to a property of e.g. the body or parts thereof such as the cardiovascular system comprising the heart activity and/or the flow behaviour and/or the flow velocity of blood or the periodicity of any moving electrical charge carrier. The acquired signals can be utilized for a synchronization of the magnetic field apparatus a time- and/or space-varying property such as the cardiac cycle and/or the blood flow behaviour.

Using the magnetic field apparatus utilizing the MHD effect, it is now possible to determine a position and/or orientation of a vessel to the main axis of the magnetic field. It was surprising that the apparatus can be used for directional analysis of a vessel. The vessel can be a pipe, a conduct or part of the vasculature of an object or body. As the MHD signal of the vessel correlates with its position in the magnetic field, the position and/or orientation of the vessel in an object can be determined. Furthermore, it is also preferred that the apparatus is used for the determination of a flow of a liquid, by analyzing various properties of the liquid, such as velocity, pressure, density and temperature as functions of space and time. The liquid can be a body fluid or any liquid flowing through an object.

It is also preferred that the apparatus is used for the quantification and characterisation of a magnetic field. An object can be placed at various spatial coordinates within a magnetic field, wherein electric charge carriers are flowing in the object. At least one sensor can measure the interaction between the electric charge carriers and the magnetic field. The MHD signal which is determined by the apparatus is proportional to the magnetic field, allowing for an assessment of the (in)homogeneity of the magnetic field. It was surprising that using the apparatus, a simple and quick quantification and characterization of a magnetic field can be established without the need of special equipment. It is possible to perform the assessment during normal usage of the magnetic field.

In a preferred embodiment, the apparatus can be used for imaging of structural and/or functional abilities of the object or parts thereof. With the apparatus it is possible to structurally and/or functionally analyze an object or parts thereof. The object can be a living or a non-living object such as a human or animal body or a mechanic object. Parts of the object are preferably organs, tissues or vessels respectively. The apparatus can be used to image the structure of the aforementioned objects. Furthermore, it can be applied to analyze the functions of the objects too. The apparatus can provide three-dimensional analysis of global and regional functions of preferably organs with great accuracy and reproducibility, thereby enabling a reliable and quick diagnosis of abnormal conditions of e.g. an organ, preventing failure of it.

In another preferred embodiment, the apparatus is used for angiographic and cardiovascular imaging and/or spectroscopy. Angiography is preferably the imaging of flowing blood in the arteries (arteriography), veins (phlebography) or lymphatic vessels (lymphography) of the body. The intensity in these images is proportional to the velocity of the flow. There are four preferred types of angiography, time-of-flight, phase contrast angiography, non-contrast MRA which makes use of differences in the blood flow across the cardiac cycle and contrast enhanced angiography. With the apparatus it is possible to detect changes of vessels, such as changes in the lumen, diameter, contractibility, stiffness of a vessel and/or stenosis, thrombosis or embolism.

It is also preferred that the apparatus is used for cardiovascular imaging and/or spectroscopy. The preferred embodiment acquires information about the heart as it is beating and creates moving images of the heart throughout its pumping cycle. This allows to display abnormalities in cardiac chamber contraction and to show abnormal patterns of blood flow in the heart and great vessels. This allows better assessment of complex anatomic abnormalities than with other imaging techniques. The preferred apparatus has the capability to identify areas of the heart muscle that are not receiving adequate blood supply from the coronary arteries and can clearly identify areas of the muscle that have become damaged as a result of infarction. It is also preferred to use the preferred apparatus for diagnostic imaging procedure for evaluating specifically: global cardiac function and regional wall motion abnormalities, ischemic heart disease, myocardial wall thickening myocardial hypertrophy, coronary artery disease, right ventricular abnormalities, pericardial disease, cardiac tumors, valvular disease, thoracic aortic disease, pulmonary artery disease, and congenital heart disease before and after surgical repair.

It is preferred that the apparatus is used in combination with an agent affecting the magnetohydrodynamic effect. According to the invention, an agent effecting the MHD effect is preferably a fluid which is introduced into an object. It is preferred that the agent is a MR contrast agent, which are predominantly paramagnetic or ferromagnetic material. It is also preferred that the agent, which can also be referred to as MHD enhancer, changes (preferably increases) the number of electrical charge carriers in the object. The agent can also be introduced into a vessel of the object. Furthermore it is preferred, that the agent comprises a high electron density. In a human or animal body, the agent can take a different course depending on its intended functionality: intravascular (IV), extracellular (EC), or intracellular (IC). An intravascular agent by design stays in the circulatory system until it is removed by the kidneys. Extracellular agents travel through the circulatory system and pass into the extracellular fluid, but do not enter into the cells. Intracellular agents can enter into a cell. It is also preferred to use targeted agents, which accumulate in a specific tissue or liquid. The cause of the accumulation is an affinity for a specific tissue or liquid. An agent can also be referred to as a contrast agent.

The accompanying drawings are included to provide a further understanding of embodiments. Other embodiments and many of the intended advantages will be readily appreciated as they become better understood by reference to the following detailed description. The elements of the drawings do not necessarily scale to each other. Like reference numbers designate corresponding similar parts.

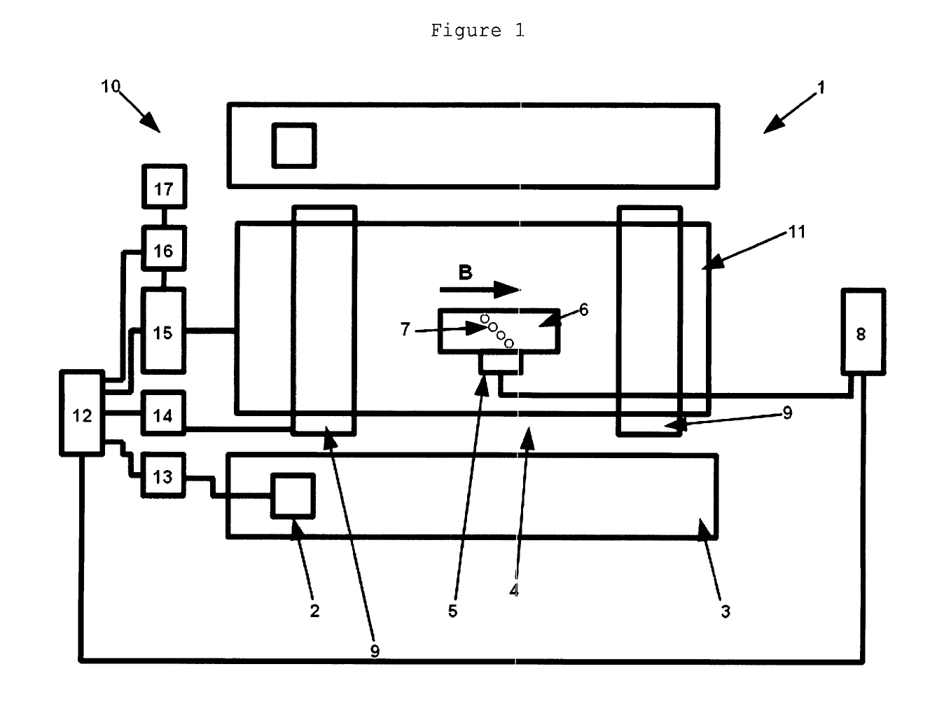

FIG. 1 illustrates a schematic view of a magnetic field apparatus according to the invention.

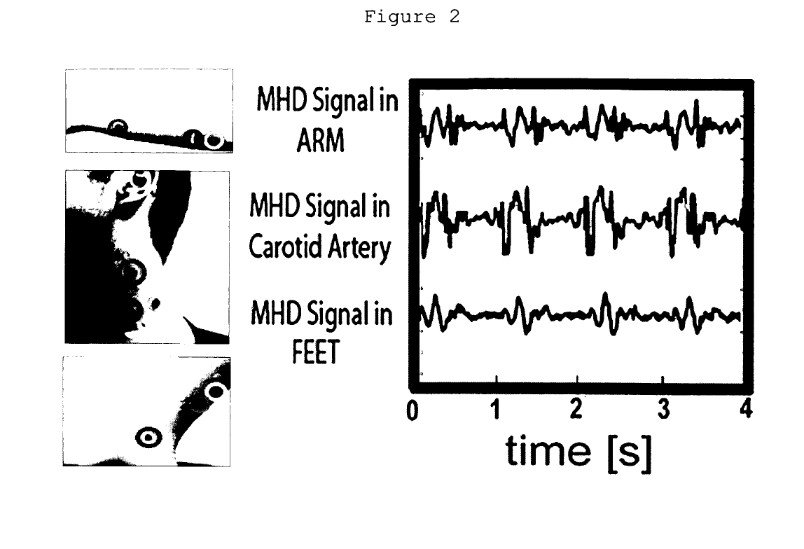

FIG. 2 illustrates a schematic picture of sensors and corresponding signals according to the invention.

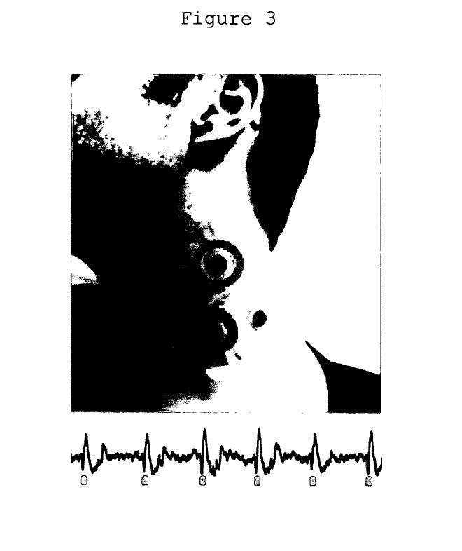

FIG. 3 illustrates a schematic picture of sensors and a corresponding signal according to the invention.

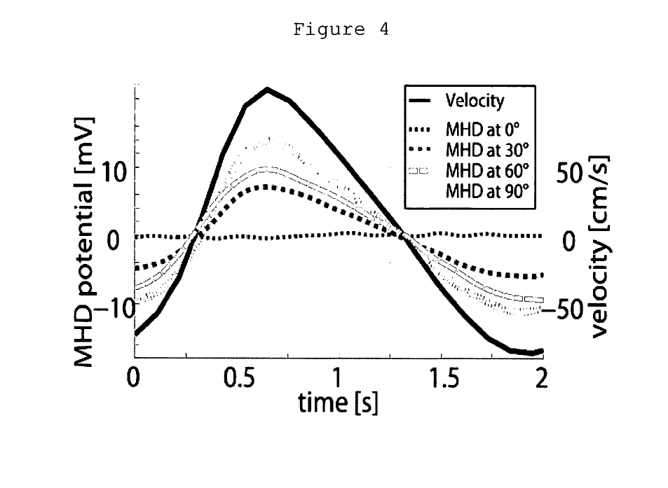

FIG. 4 illustrates a diagram of the signal behaviour in dependence of the orientation according to the invention.

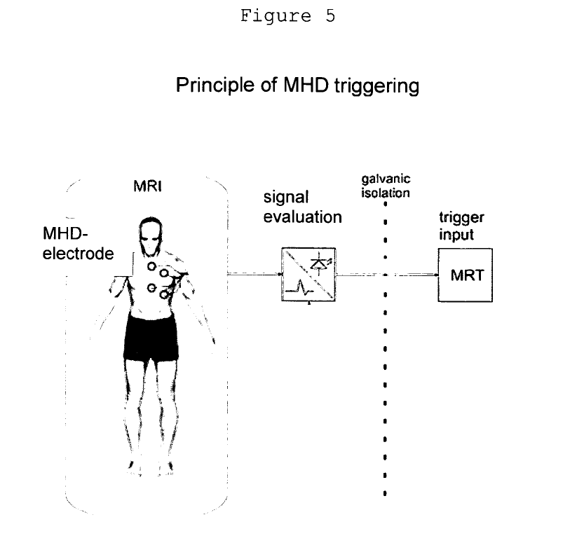

FIG. 5 illustrates schematically an magnetic field apparatus according to a preferred embodiment of the invention.

In the following detailed description, reference is made to the accompanying drawings which form a part hereof and in which are shown by way of illustration specific embodiments in which the invention may be practised. In this regard, directional terminology, such as “top” or “bottom” etc. is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

FIG. 1 shows a magnetic field apparatus 1 with a generator 2 in form of magnets or coils which generate a basic magnetic field B. The basic magnetic field B created by the generator 2 can vary spatially and/or in time or can change over time in strength, spatial distribution, temporal evolution and/or an angle. The generator 2 usually has a circular shape which is here shown in a sectional view. The generator 2 can comprise multiple magnets or coils, for the sake of clarity only one is shown. The generator 2 may be arranged in a housing 3 which can surround an opening 4 shaped for example in form of a tunnel. Inside the opening 4 the magnetic field B is generated. The magnetic field B is directed through the opening 4 in direction of the arrow. The generator 2 is adapted to achieve a homogeneous field distribution.

The magnetic field apparatus 1 further has a sensor 5 placed inside the magnetic field. The sensor 5 is attached to an object 6 with electrical charge carriers 7. The object 6 can be a physical object or a body of a human or an animal. The electrical charge carriers 7 and the magnetic field B are in relative motion to each other so that an electrical potential is generated by the magnetic field B which can be measured by the sensor 5. The basis for this measurement is the magnetohydrodynamic (MHD) effect.

The sensor 5 can be an electric field sensor adapted to measure an electrical potential difference in the magnetic field B at two measurement points. The sensor 5 can include electrodes or probes. The sensor 5 is connected to a signal evaluation device 8 which post processes, filters and/or evaluates the signal of the sensor 5. More than one sensor can be employed.

The magnetic field apparatus can include a second generator 9 which can be realised in form of time and spatially varying magnetic fields, which for example can be generated by additional coils, a specific version is commonly called gradient coil. The additional coils 9 can work independently from the main magnetic field or their field can be superimposed to the main magnetic field. Only two additional coils 9 are depicted for the ease of understanding. It is common to use three additional coils, one for each direction but even more additional coils can be implemented. The additional coils 9 can adapt or modulate the basic magnetic field B by generating gradient fields or they can generate a test field independent of the basic field B. The test field can be identical to the gradient fields. The second generator 9 can also be realised in form of one or more generators external to the housing 3.

The magnetic field apparatus 1 can be configured as a magnetic resonance (MR) apparatus 10. This can be a magnetic resonance image (MRI) device or a nuclear magnetic resonance (NMR) device or any other device or system using magnetic resonance.

The MR/ESR apparatus 10 includes a high frequency (HF) coil 11 to send HF excitation pulses and/or to detect signal inherent to nuclear magnetic resonance of electron spin resonance. The HF coil 11 is usually located inside the housing 3 near to the object to be examined.

The MR apparatus 10 includes a control unit 12 which controls the operation of the MR apparatus 10. The sensor 5 is connected to the control unit 12, either directly or indirectly via e.g. the signal evaluation device 8. The functions of the signal evaluation device 8 can be implemented in the control unit 12. The control unit 12 controls several subunits which can be internal or external to the control unit 12 and which can be implemented in software as well.

A main magnetic field control 13 controls the generator 2 and a gradient field control 14 controls the secondary generator 9. For the secondary generator an external control i.e. independent from the MR apparatus control is also included.

HF control 15 includes an HF generator and HF coil for exciting an object and therewith inducing transition of spins between energy levels which generates a magnetic resonance signals when the spins return to the equilibrium. The HF coil 11 acts as a transmitter and/or as a receiver. The received MR signals are transmitted to an imager or spectrometer 16. Here, the acquisition, analysis and/or reconstruction of MR data takes place. The imager 16 can be integrated into the control unit 12 and realised in hardware and/or software. The term acquisition can also encompass the whole process or part thereof of placing the object 6 inside the opening 4, generating the magnetic field or fields, exciting the HF coil 11 and the like.

The results or part of the results can be displayed at a display 17. The results can be an image of the object 6 if an imaging process was chosen or it can be an analysis for example if a spectrography process was chosen.

In the following different applications are discussed.

FIGS. 2 and 3 show MHD signal behaviours measured in different regions of a human body. The sensors 5 employed here are electrodes. Three electrodes are shown for each measurement. However, two electrodes are sufficient to measure the potential difference induced by the magnetic field B.

The measurement occurs simultaneously with the heart activity and the blood flow behaviour respectively. The potential measurement of MHD induced signals in a region of the body allows conclusions with regard to heart activity, blood flow behaviour, blood flow velocity or flow of any other liquid containing electrical charge carriers. If electrodes are positioned in the heart area the recorded MHD signal may be superimposed by the ECG signal. However, good identification of the MHD signal is given.

When the target area is at a distance to the heart area, for example at the fore arm, the neck (carotid artery) or the feet the signals are mainly MHD induced. In FIG. 2 the corresponding signal behaviours are shown. The amplitude of the MHD signal correlates with the blood activity inside the vasculature.

It can be seen that the peaks of the signals which can be utilised to trigger or synchronise the MR imaging, the acquisition, analysis and/or reconstruction of MR data are occur at the time with respect to the cardiac cycle i.e. independent from the distance to the heart.

These signal behaviours can be used for a correlation with the cardiac cycle and for the synchronisation with the cardiac cycle and the blood flow behaviours respectively. In FIG. 3 the marker under the signal indicate the corresponding trigger points.

This allows for a detection of heart activity and a detection of blood flow respectively with an electrical measurement in a magnetic field B of a magnetic field apparatus 1 or an MR apparatus 10. The electrical measurement is realised by electrodes or probes 5 which measure the electrical potential generated by the interaction between electrical charge carriers (here inside the blood) and the magnetic field B.

For the first time, a trigger activator is realised locally at the target area of interest. Vascular imaging can be better synchronised as a phase correct MR data acquisition and reconstruction with regard to the heart activity or to the blood flow behaviour is possible. The trigger information is directly accessed in the target region. Accordingly, there is no intrinsic time delay between the cardiac cycle and the cycle of blood flow behaviour respectively at the target region and the trigger mechanism, here the MHD signal behaviour, which usually occurs when the trigger signal is derived from areas outside of the target region due to the travel time between the “trigger area” and the target region.

FIG. 4 shows the correlation of the MHD signal and the directional dependence of the MHD signal with regard to a flow of electrical charge carriers 7 positioned in the magnetic field B of the magnetic field apparatus 1.

Using the MHD effect it is possible to gain directional information. This can be implemented by changing the orientation of a vascular or of vessels in general with regard to the magnetic field B. The effect of the change of orientation is shown in FIG. 4. In case of a directional dependent maximum of the MHD signal the vasculature or vessel is orientated perpendicular to the magnetic field B. In the case of a parallel orientation of the vascular or vessel to the magnetic field no MHD signal or a minimum of the MHD signal is present.

Instead of changing the orientation of the vascular or the vessel the orientation of the magnetic field can be changed. This can be achieved by superimposing the basic magnetic field with additional magnetic field vectors like a test field or one or more gradient fields from one or more gradient coils 9. The resulting magnetic field can be switched through different orientations until the maximum of the MHD signal is detected. This allows to determine a main axis of a vascular or a vessel or a directional dependence of a flow with the main MR magnet 2, a secondary generator like a gradient coil 9 or a combination of both. The secondary generator 9 can include magnets which are placed mechanically or an array of magnetic coils which are driven electronically to create a freely adjustable magnetic field vector.

The above described determination of a main axis and of a directional dependence of a flow can be used to access the orientation of a vasculature before an MR imaging, in material sciences, geology or archaeology. The function of a prosthetic heart valve can be examined as well. However, the function of a prosthetic heart valve can also be examined under a broader approach than the determination of the a main axis.

The MHD induced difference in electrical potential of the magnetic field apparatus 1 can further be used to characterise a magnetic field. To this, the object 6 positioned in the magnetic field B of the magnetic field apparatus 1 is a probe and the sensor 5 is attached to the probe 6 to measure the potential difference between two measuring points generated by the interaction of electrical charge carriers 7 of the probe 6 and the magnetic field B.

The probe 6 is can be placed at any arbitrary position inside the magnetic field B so that the magnetic field can be surveyed. At each measurement position the probe 6 is positioned and one or more measurements are taken. The strength, spatial distribution, temporal evolution or variation and/or one or more angles of the magnetic field B are measured. The measurements can be combined to create a magnetic map of the magnetic field B. Ideally, the flow of magnetic charge carriers 7 is reproducible or standardised so that the measurements are directly comparable. Alternatively, correction factors can be introduced.

The probe 6 can have a vessel through which the electrical charge carriers 7 flow. The interaction between the electrical charge carriers 7 and the magnetic field B is measured. The signals measured at different coordinates inside the magnetic field B usually in form of voltages are proportional to the magnetic field B. In order to enhance the sensitivity of the measurement the distance between the measuring points of the sensor 5 and/or the flow velocity of the charge carriers 7 can be increased.

The above measurement can for example be used to characterise and quantify the magnetic field, to create a magnetic map of the magnetic field and/or to take measures to enhance the homogeneity of the magnet field using passive shimming approaches or actively adapted controls 13, 14 of the main magnet field B and/or gradient field(s). Further, the measurement can be part of a quality control and be used to initially calibrate and/or to support the maintenance and the operation of the magnet field apparatus 1 or the MR apparatus 10.

A contrast agent for example a special MHD enhancer which increases the number of electrical charge carriers or introduces them at all can be introduced into the object 6 or into a vessel. The contrast agent enables or enhances the MHD effect. The contrast agent comprises a large number of electrical charge carriers for example a high electron density. Suitable is for example a NaCl solution.

Distilled water or transformer oils like SF6 for example are void or almost void of electrical charge carriers and are therefore not suitable to be measured using the MHD effect. In order to make devices with these fluids suitable for the above described applications a contrast agent introducing electrical charge carriers 7 is added to the devices.

FIG. 5 illustrates schematically an magnetic field apparatus according to a preferred embodiment of the invention. The magnetic field apparatus can be for example an MR apparatus. The MHD effect is dependent on the strength of the magnetic field, the length of the distance travelled by the electric charge carriers between measuring point, the velocity of the electric charge carriers, the concentration, density and the flow of the carriers in correlation to the magnetic field. To use the MHD effect for triggering, the electrical potential difference derived from the interaction of the electrical charge carriers and the magnetic field being in relative motion to each is measured by one or more sensors at least at two measuring points. The measurement can take place in any region of a object or body, allowing conclusions with regard to the heart activity and/or the flow behaviour and/or the flow velocity of blood or the periodicity of any moving electrical charge carrier. This enables to generate a trigger information directly at the target of the imaging.

1. Magnetic field apparatus, comprising:
a generator configured to generate a magnetic field of the magnetic field apparatus,
a sensor configured to measure an interaction between electrical charge carriers in an object and the magnetic field, wherein the electrical charge carriers and the magnetic field are in relative motion to each other.

2. The magnetic field apparatus according to claim 1, wherein the sensor is an electric field sensor.

3. The magnetic field apparatus according to claim 1, comprising at least two sensors.

4. The magnetic field apparatus according to claim 1, wherein the sensor is configured to measure an electrical potential difference in the magnetic field of the magnetic field apparatus.

5. The magnetic field apparatus according to claim 1, wherein the magnetic field apparatus is an MR apparatus and comprises a control unit for synchronization of acquisition, analysis and/or reconstruction of MR data, wherein the control unit is in communication with the sensor.

6. The magnetic field apparatus according to claim 1, comprising a secondary generator for generating a test field, wherein the sensor detects direction of a vessel of the object based on the test field.

7. The magnetic field apparatus according to claim 1, wherein the object is a probe positionable in the magnetic field and wherein the sensor is attached to the probe for measuring strength, spatial distribution, temporal evolution and/or an angle of the magnetic field.

8. Method for operating a magnetic field apparatus, the method comprising:
measuring the interaction between electrical charge carriers of an object and the magnetic field of the magnetic field apparatus;
synchronizing acquisition, analysis and/or reconstruction of MR data of the magnetic field apparatus based on the measured interaction; and/or
determining a direction of a vessel of the object based on the measured interaction; and/or
characterizing a magnetic field of the magnetic field apparatus based on the measured interaction.

9. The method according to claim 8, wherein a magnetohydrodynamic effect is utilized in the measuring.

10. The method according to claim 8, wherein an electrical potential difference in the magnetic field of the magnetic field apparatus is measured.

11. Method for imaging and/or spectroscopy, comprising:
providing a magnetic field apparatus employing a magnetohydrodynamic effect, wherein the magnetic field apparatus comprises a generator and a sensor, wherein the generator generates a magnetic field of the magnetic filed apparatus and the sensor measures the interaction between electrical charge carriers in an object and the magnetic field of the magnetic filed apparatus wherein the electrical charge carriers and the magnetic field are in relative motion to each other.

12. The method according to claim 11, wherein acquisition, analysis and/or reconstruction of MR data is synchronized with at least one time- and/or space-varying property of an object or parts thereof.

13. The method of claim 11, wherein a position and/or orientation of a vessel of the object to a main axis of the magnetic field is determined.

14. The method of claim 11, wherein flow of a liquid is determined.

15. The method of claim 11, wherein a magnetic field is quantified and characterized.

16. The method of claim 11, wherein structural and/or functional abilities of the object or parts thereof are imaged.

17. The method of claim 11, wherein the imaging and/or spectroscopy is angiographic and cardiovascular imaging and/or spectroscopy.

18. The method of claim 11, wherein an agent affecting the magnetohydrodynamic effect is employed in the method.

19. The method of claim 11, wherein the sensor measures an electrical potential difference in the magnetic field of the magnetic field apparatus.

20. The method of claim 11, wherein the object is a probe positioned in the magnetic field and wherein the sensor is attached to the probe and measures strength, spatial distribution, temporal evolution and/or an angle of the magnetic field.
